(19) United States
(12) Patent Application Publication
(10) Pub. No.: US 2026/0164992 A1
(43) Pub. Date: Jun. 11, 2026

(54) DISPLAY DEVICE AND ELECTRONIC DEVICE INCLUDING DISPLAY DEVICE

(71) Applicant: Samsung Display Co., Ltd., Yongin-Si (KR)

(72) Inventors: Won Jong BAEK, Yongin-si (KR); Jeong Seok LEE, Yongin-si (KR); Chae Kyeong LEE, Yongin-si (KR); Jong Seok JOO, Yongin-si (KR); Soon Ryong PARK, Yongin-si (KR)

(21) Appl. No.: 19/180,519

(22) Filed: Apr. 16, 2025

(30) Foreign Application Priority Data
Jun. 4, 2024 (KR) 10-2024-0073195

(51) Int. Cl. H10K 59/80; H10H 29/852; H10H 29/855

(52) U.S. Cl. CPC H10K 59/873; H10H 29/852; H10H 29/855; H10K 59/8791

(57) ABSTRACT

The display device includes a display panel for displaying an image and a cover window disposed on the display panel. The cover window includes a cover glass layer, and at least one coating layer disposed on the cover glass layer. The display panel has a first color difference value in a color coordinate system, the at least one coating layer has a second color difference value in the color coordinate system, and a sum of the first color difference value and the second color difference value is adjacent to an origin of the color coordinate system.

### CROSS-REFERENCE TO RELATED APPLICATION

This application claims priority to and the benefit of Korean Patent Application No. 10-2024-0073195, filed in the Korean Intellectual Property Office on Jun. 4, 2024, the entire contents of which are incorporated herein by reference.

### BACKGROUND

### Field

The present disclosure relates to a display device and an electronic device including the display device.

### Description of the Related Art

The proliferation of multimedia into a wide variety of applications from automobiles to appliances has made display devices increasingly important. In response, various types of display devices such as an organic light emitting display (OLED), a liquid crystal display (LCD), etc. have been developed and are being used today.

A modern display device may include a transparent cover window in front of a display panel, and a user may view through the window to see an image that the display panel presents. Since the cover window is on the outermost part of the display device, the cover window needs to be resistant to external shocks to protect the display panel. The cover window on the display panel, however, may cause a perceived heterogeneity in the colors on the display panel, and the research is underway to reduce the perceived heterogeneity.

The above is only intended to provide an understanding of background technology that maya be related to the present disclosure, but the above content may not be prior art known to those of ordinary skill in the art.

### SUMMARY

Embodiments disclosed herein may provide a display device with improved display quality. For example, a display device can improve display quality by applying a predetermined color difference value to a coating layer to compensate for a color difference value of a display panel.

A display device according to an embodiment of the present disclosure may include a display panel displaying an image and a cover window disposed on the display panel. The cover window includes a cover glass layer and at least one coating layer disposed on the cover glass layer. The display panel has a first color difference value in a color coordinate system, the at least one coating layer has a second color difference value in the color coordinate system, and a sum of the first color difference value and the second color difference value is adjacent to an origin of the color coordinate system.

The first color difference value may be a measurement value of light that reaches the display panel and is reflected therefrom, and the second color difference value may be a measurement value of light that reaches the at least one coating layer and is reflected therefrom.

The first and second color difference values may be SCI (specular component included) reflectance or SCE (specular component excluded) reflectance.

The sum of the first color difference value and the second color difference value may be in a range from −1 to 1.

Each of the first and second color difference values may include a first color coordinate and a second color coordinate, and a sum of the first color coordinate of the first color difference value and the first color coordinate of the second color difference value may be in a range from −1 to 1, and a sum of the second color coordinate of the first color difference value and the second color coordinate of the second color difference value may be in a range from −1 to 1.

The first color coordinate of the first color difference value may be in a range from −3 to 3, and the second color coordinate of the first color difference value may be in a range from −3 to 3.

The second color difference value may be determined based on Equation 1 below.

$${a}^{*} \_ 2 \geq {k}_{a} \times ( {a}^{*} \_ 1 ) + α , \qquad ( Equation 1 )$$

$${b}^{*} \_ 2 \geq {k}_{b} \times ( {b}^{*} \_ 1 ) + β ,$$

$$0.5 \leq {k}_{a} , {k}_{b} \leq 1 , - 0.6 \leq α \leq 0 , - 3 \leq β \leq 1.5$$

Here, a*_1 may be the first color coordinate of the first color difference value, a*_2 may be the first color coordinate of the second color difference value, b*_1 may be the second color coordinate of the first color difference value, and b*_2 may be the second color coordinate of the second color difference value.

When the first and second color coordinates are positive values, the first and second color coordinates may correspond to red and yellow colors, respectively, and when the first and second color coordinates are negative values, the first and second color coordinates may correspond to green and blue colors, respectively.

The second color difference value may be set to have a black color when the display panel is in an off state.

The display device may not include a polarization layer.

The at least one coating layer may include an anti-reflection coating layer, an anti-finger coating layer, or an anti-glare coating layer.

The at least one coating layer may include a first coating layer disposed on the cover glass, and a second coating layer disposed on the first coating layer. The first coating layer may have a third color difference value in the color coordinate system, the second coating layer may have a fourth color difference value in the color coordinate system, and a sum of the first color difference value, the third color difference value, and the fourth color difference value may be adjacent to the origin of the color coordinate system.

A sum of the first color difference value, the third color difference value, and the fourth color difference value may be in a range from −1 to 1.

The display device may further include a bonding layer disposed between the display panel and the cover glass layer.

The display panel may include a substrate, a circuit element layer disposed on the substrate and including a plurality of transistors, and a light emitting element layer disposed on the circuit element layer and including light emitting elements respectively connected to the plurality of transistors.

An electronic device includes a processor to provide input image data and a display device to display an image based on the input image data, wherein the display device includes a display panel capable of displaying an image and a cover window disposed on the display panel, wherein the cover window includes a cover glass layer and at least one coating layer disposed on the cover glass layer, and the display panel has a first color difference value in a color coordinate system, the at least one coating layer has a second color difference value in the color coordinate system, and a sum of the first color difference value and the second color difference value is adjacent to an origin of the color coordinate system.

The first color difference value is a measurement value of light that reaches the display panel and is reflected therefrom, and the second color difference value is a measurement value of light that reaches the at least one coating layer and is reflected therefrom.

Each color coordinate of the sum of the first color difference value and the second color difference value is in a range from −1 to 1.

The at least one coating layer includes a first coating layer on the cover glass, and a second coating layer on the first coating layer, the first coating layer has a third color difference value in the color coordinate system, the second coating layer has a fourth color difference value in the color coordinate system, and a sum of the first color difference value, the third color difference value, and the fourth color difference value is adjacent to the origin of the color coordinate system.

A sum of the first color difference value, the third color difference value, and the fourth color difference value is in a range from −1 to 1.

### BRIEF DESCRIPTION OF THE DRAWINGS

FIG. 1 is a perspective view schematically showing a display device according to an embodiment of the present disclosure.

FIG. 2 is a plan view showing an embodiment of the display panel of FIG. 1.

FIG. 3 is a cross-sectional view taken along a line I-I′ of FIG. 1.

FIG. 4 is a cross-sectional view showing an embodiment of a cover window of FIG. 3.

FIG. 5 is a plan view showing an embodiment of one of the pixels of FIG. 2.

FIG. 6 is a cross-sectional view taken along a line II-II′ of FIG. 5.

FIG. 7 is a plot showing an example of color difference values according to some embodiments of the present disclosure.

FIG. 8 is a schematic block diagram illustrating an electronic device including a display device in accordance with an embodiment.

FIG. 9 is a schematic diagram illustrating an example where the electronic device of FIG. 8 is a smartphone.

FIG. 10 is a schematic diagram illustrating an example where the electronic device of FIG. 8 is a tablet computer.

### DETAILED DESCRIPTION OF THE EMBODIMENTS

Example embodiments are described in detail herein with reference to the attached drawings. The following may only components or elements that are necessary to understand structures or operations according to the example embodiments, and the description of other components or elements may be omitted to avoid obscuring salient features of the disclosed embodiments. Additionally, the present disclosure is not limited to the embodiments illustrated in the drawings or expressly described herein, and embodiments in accordance with this disclosure may take other forms. However, the embodiments described herein are provided to explain in detail enough to enable those skilled in the art to easily implement the technical ideas of the present disclosure.

Throughout the specification, a part said to be “connected” to another part includes not only the case where the parts are “directly connected” but also the case where the parts are “indirectly connected” with one or more other elements therebetween. In this disclosure below, when one structure “includes” some elements, the structure may include only those elements or may include other elements as well as those elements if there is no specific limitation. The phrase “at least one of X, Y, and Z”, and “at least one selected from the group consisting of X, Y, and Z” may be interpreted as an X, a Y, a Z, or any combination (e.g., XYZ, XYY, YZ, and ZZ) of two or more among X, Y, and Z. Here, “and/or” includes any combination of one or more of the related constituents.

Here, terms such as first, second, etc. may be used to describe various components, but these components are not limited to these terms. These terms are used only to distinguish one constituent element from another constituent element. Accordingly, the first component may be referred to as the second component within the scope of what is disclosed herein.

Spatially relative terms such as “below,” “above,” etc. may be used for descriptive purposes, thereby describing the relationship of one element or feature to another element(s) or feature(s) as shown in the drawings. Spatially relative terms are intended to include different directions in use, operation, and/or manufacture in addition to the directions depicted in the drawings. For example, if the device shown in the drawings is turned over, elements depicted as being “below” other elements or features may be “above” the other elements or features. Additionally, the devices may have different orientations (e.g., rotated by 90 degrees or in other orientations), and thus the spatially relative terms used herein should be interpreted accordingly.

Various embodiments are described with reference to drawings that may schematically show ideal embodiments. Accordingly, the shapes of features in physical embodiments may vary depending, for example, on tolerances and/or manufacturing techniques. Accordingly, embodiments disclosed herein should not be construed as being limited to the specific shapes shown and should be construed to include changes in shapes that occur, for example, as a result of manufacturing. As such, the shapes shown in the drawings may not depict the actual sizes of features or shapes of areas of the device, and the present embodiments are not limited to the specifics of the drawings.

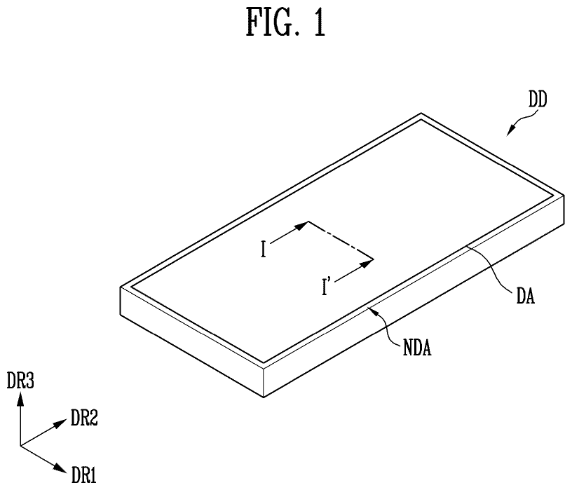

FIG. 1 is a perspective view schematically showing a display device DD according to an embodiment of the present disclosure.

Referring to FIG. 1, the display device DD is an electronic device having a display surface formed on at least one surface or face thereof. The display device DD may be, for example, a smartphone, a television, a tablet PC, a mobile phone, a video phone, an e-book reader, a desktop PC, a laptop PC, a netbook computer, a workstation, a server, a PDA, a portable multimedia player (PMP), an MP3 player, a medical equipment, a camera, a wearable, and the like.

The display device DD may have various shapes, and FIG. 1 shows an example in which the display device DD has the shape of a rectangular plate having two pairs of sides parallel to each other, but the present disclosure is not limited thereto. When the display device DD is shaped as a rectangular plate, one pair of sides of the two pairs of sides may be longer than the other pair of sides. FIG. 1 further shows an example in which corners of the display device DD are angled corners formed at intersections of straight sides, but the present disclosure is not limited thereto. For example, the display device DD provided may be shaped as a rectangular plate having rounded corners where the long sides meet the short sides.

For convenience of description, FIG. 1 illustrates a case where the short sides of the display device DD extend in a first direction DR1 and the long sides of the display device DD extend in a second direction DR2. A third direction DR3 may be perpendicular to the first and second directions DR1 and DR2.

In an embodiment of the present disclosure, at least a portion of the display device DD may be flexible, and the display device DD may be folded at the flexible portion.

The display device DD may include a display area DA that displays an image and a non-display area NDA on at least one side of the display area DA. The non-display area NDA may be an area on which the image is not displayed. However, the present disclosure is not limited thereto. A shape of the display area DA and a shape of the non-display area NDA may be related to each other, e.g., the non-display area NDA may surround a perimeter of the display area DA.

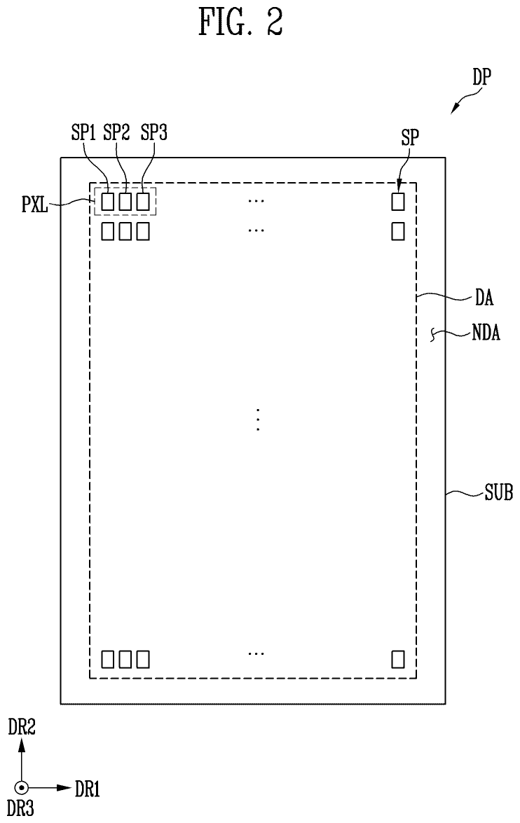

FIG. 2 is a plan view showing an embodiment of a display panel DP that may be employed in the display device DD of FIG. 1.

Referring to FIG. 2, the display device DD may include a display panel DP that displays an image that includes a substrate SUB on which pixels PXL are formed. The display panel DP and the substrate SUB may include a display area DA and a non-display area NDA. The display area DA of the display panel DP may constitute a screen on which an image is displayed, and the non-display area NDA may be the remaining area of the display panel excluding the display area DA.

For convenience of description, FIG. 2 shows only some of the structure of the display panel DP, particularly some of the structure of the display panel DP associated with the display area DA. However, although not shown in FIG. 2, at least one driving circuit (e.g., at least one of a scan driver, a data driver, and a light emission driver), lines, and/or pads may be further disposed on the display panel DP.

A plurality of sub-pixels SP may be disposed in the display area DA. Two or more sub-pixels among the plurality of sub-pixels SP may constitute one pixel PXL. FIG. 2 shows an example in which one pixel PXL includes a first sub-pixel SP1, a second sub-pixel SP2, and a third sub-pixel SP3. However, embodiments in accordance with the present disclosure are not limited thereto. For example, one pixel PXL may include one first sub-pixel SP1, two second sub-pixels SP2, and one third sub-pixel SP3. FIG. 2, for ease of illustration, identifies only one pixel PXL. Other pixels (not expressly shown in FIG. 2) may also include three subpixels SP, e.g., first sub-pixel SP1, second sub-pixel SP2, and third sub-pixel SP3. Herein, at least one sub-pixel among the first sub-pixel SP1, the second sub-pixel SP2, and the third sub-pixel SP3 may be generically referred to as the “sub-pixel SP” or the “sub-pixels SP”.

The sub-pixels SP may be arranged regularly according to a stripe or PENTILE™ arrangement structure. However, the arrangement structure of the sub-pixels SP is not limited thereto, and the sub-pixels SP may be arranged in the display area DA in various structures and/or according to various placement methods.

Sub-pixels SP may be of two or more types that emit light of different colors. For example, in the display area DA, the first sub-pixel SP1 may emit light of a first color, the second sub-pixel SP2 may emit light of a second color, and the third sub-pixel SP3 may emit light of a third color. A set of at least one of each of the first to third sub-pixels SP1 to SP3 that are adjacent to each other may form one pixel PXL capable of emitting light of various colors. For example, the first sub-pixel SP1 may be a red pixel that emits red light, the second sub-pixel SP2 may be a green pixel that emits green light, and the third sub-pixel SP3 may be a blue pixel that emits blue light, but embodiments of the present disclosure are not limited thereto.

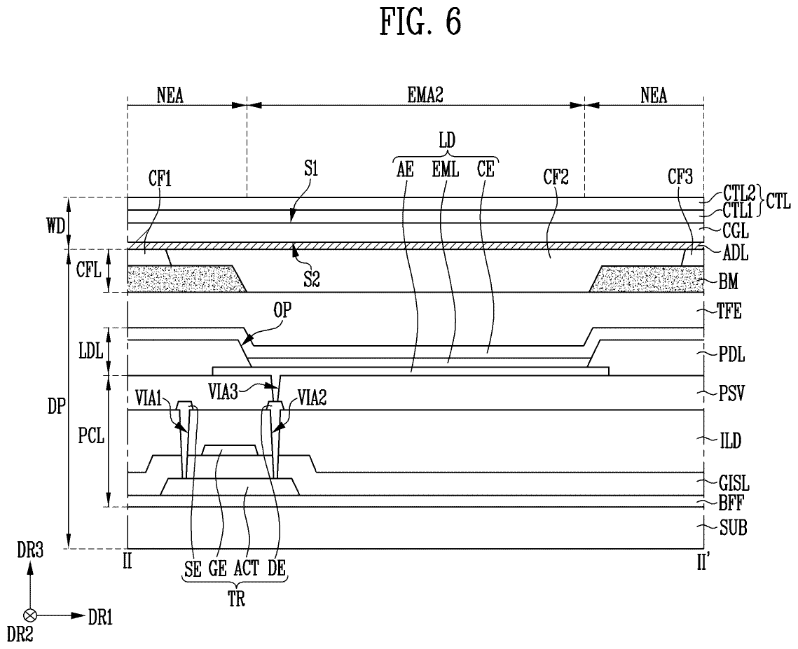

Each of the first sub-pixel SP1, the second sub-pixel SP2, and the third sub-pixel SP3 may include a light emitting element LD (see FIG. 6) as a light source. Accordingly, the first sub-pixel SP1, the second sub-pixel SP2, and the third sub-pixel SP3 may respectively include light emitting elements LD that can respectively emit the first color light, the second color light, and the third color light.

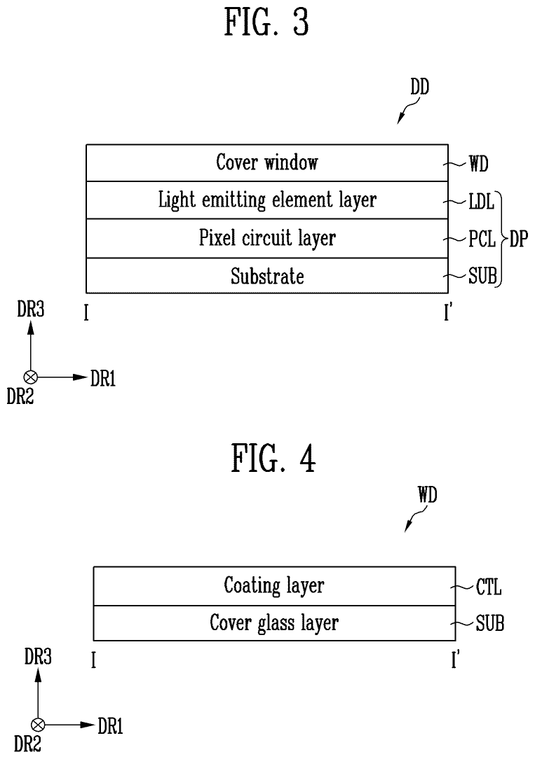

FIG. 3 is a cross-sectional view taken along a line I-I′ of FIG. 1.

Referring to FIG. 3, the display device DD may include a display panel DP and a cover window WD. The display panel DP may include the substrate SUB, a pixel circuit layer PCL, and a light emitting element layer LDL.

The substrate SUB may include a semiconductor substrate. For example, the substrate SUB may include a silicon bulk wafer or an epitaxial wafer. The epitaxial wafer may include a crystalline material layer, that is, an epitaxial layer, grown by an epitaxial process on a bulk substrate. The substrate SUB is not limited to bulk wafers or epitaxial wafers and may be formed using various wafers such as polished wafers, annealed wafers, and SOI (silicon on insulator) wafers.

The pixel circuit layer PCL may be disposed on the substrate SUB and may include pixel circuits for driving the sub-pixels SP formed using the light emitting element layer LDL, e.g., each sub-pixel SP including a light emitting element LD (see FIG. 6) formed in the light emitting element layer LDL. The pixel circuit layer PCL may include a base layer, conductive layers for forming the pixel circuits, and insulating layers disposed on the conductive layers. The pixel circuits may include circuit elements including a plurality of transistors and signal lines connected to the transistors. For example, the transistors may be a metal oxide semiconductor field effect transistor (MOSFET) but are not limited thereto. Additionally, each of the transistors may include a gate electrode, source/drain regions, and a channel region.

The light emitting element layer LDL may be disposed on the pixel circuit layer PCL. The light emitting element layer LDL may include the light emitting elements LD. The light emitting elements LD may be disposed in the sub-pixels SP, and each of the light emitting elements LD may be connected to at least one transistor TR (see FIG. 6). According to the embodiment, each of the light emitting elements LD may include one of an organic light emitting diode, an inorganic light emitting diode, a quantum dot/well light emitting diode, etc. However, the present embodiments are not limited thereto.

The cover window WD may be disposed on the light emitting element layer LDL. The cover window WD may cover an upper surface of the display panel DP and may protect the upper surface of the display panel DP. The cover window WD may protect the display panel DP from external shock and may provide an input surface and/or a display surface to the user. The cover window WD may be combined with or attached to the display panel DP using an optically transparent adhesive (or bonding) member (not shown). Details regarding the cover window WD according to specific embodiments are described below with reference to FIG. 4.

The cover window WD may have a multi-layer structure including one or more of a glass substrate, a plastic film, and a plastic substrate. A continuous process may form such a multi-layer structure on the display panel, or a bonding process may attach a multi-layer structure of the cover window WD to the display panel DP using an adhesive layer. The cover window WD may be fully or partially flexible.

A touch sensor (not shown) may be disposed between the display panel DP and the cover window WD. The touch sensor may be disposed directly on the display surface (or upper surface) where the image is projected from the display panel DP and where the touch sensor may receive a user's touch input.

FIG. 4 is a cross-sectional view showing an embodiment of the cover window WD of FIG. 3.

Referring to FIG. 4, the cover window WD may include a cover glass layer CGL and a coating layer CTL on one surface of the cover glass layer CGL.

The cover glass layer CGL may have a shape corresponding to the display panel DP. For example, the cover glass layer CGL may have a plate shape with both major surfaces or faces being parallel to each other.

The cover glass layer CGL may protect the display panel DP. The cover glass layer CGL may particularly protect the display panel DP from external pressure. Accordingly, the cover glass layer CGL may include a material having a rigidity suitable for protecting the display panel DP from external pressure. For example, the cover glass layer CGL may include a glass material. For example, the cover glass layer CGL may include tempered glass. Additionally, the cover glass layer CGL may further include various materials to improve durability, surface smoothness, and transparency. For example, the cover glass layer CGL may further include alkali metal, alkaline earth metal, and oxides thereof. The cover glass layer CGL is not limited to a glass material and may contain various materials at various ratios.

The coating layer CTL may entirely cover the cover glass layer CGL. The coating layer CTL may be disposed on one surface that provides an input surface and/or a display surface to the user among both major surfaces of the cover glass layer CGL. For example, the coating layer CTL may form a surface directly exposed to the user. For example, the coating layer CTL may provide a surface that contacts the user's finger, a stylus pen, and other external objects or substances. However, the embodiments are not limited thereto. For example, an additional functional layer may be disposed on the coating layer CTL, so that the coating layer CTL is not directly exposed to the user.

The coating layer CTL may include at least one of an anti-reflection coating layer, an anti-finger coating layer, and an anti-glare coating layer. For example, the coating layer CTL may include an anti-reflection coating layer that minimizes external light reflection on the surface of the cover glass layer CGL. The coating layer CTL may include an anti-finger coating layer that prevents contamination of the user's handprints (e.g., fingerprint marks). Alternatively, the coating layer CTL may include an anti-glare coating layer that prevents glare by diffusely reflecting light incident on the surface of the cover window CD. However, this is an example, and the coating layer CTL may have various functions depending on the characteristics required for the cover window WD. For example, the coating layer CTL may be a hard coating layer that increases the hardness of the display panel DP.

FIG. 4 shows the coating layer CTL as a single layer, but the coating layer CTL is not limited thereto. The coating layer CTL may include a plurality of coating layers with various functions. For example, the coating layer CTL may include an anti-reflection coating layer adjacent to the cover glass layer CGL and an anti-fingerprint coating layer on the cover glass layer CGL with an anti-reflection coating layer interposed therebetween. Additionally, the coating layer CTL may be formed in the form of a film with various functions.

In some embodiments, the display panel DP may not include a polarization layer. Since the polarization layer blocks reflection of external light, when the display panel DP does not include a polarization layer, the reflectance of external light from the display panel DP may increase. When the display panel DP, which does not include the polarization layer, and the coating layer CTL are laminated, a problem may occur in which a blue color rather than a black color is visible when the display panel DP is in an off state.

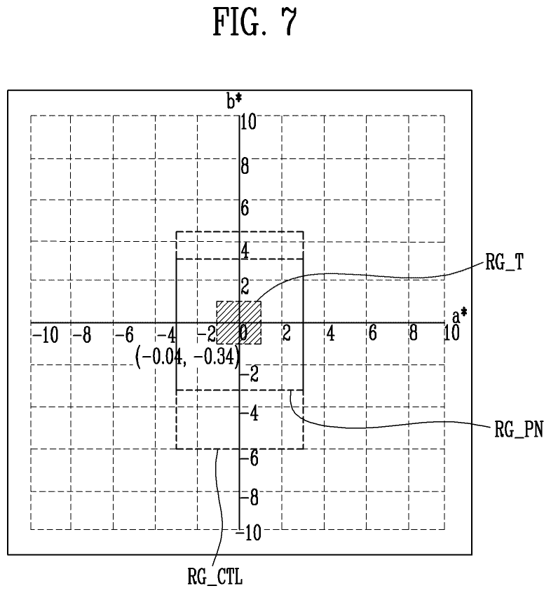

According to an embodiment of the present disclosure, the coating layer CTL may have a color difference value that was chosen based on the color difference value of the display panel DP, so the black color may be visible when the display panel DP is in the off state. Details regarding the color difference value of the coating layer CTL according to an example embodiment is described below with reference to FIGS. 6 and 7.

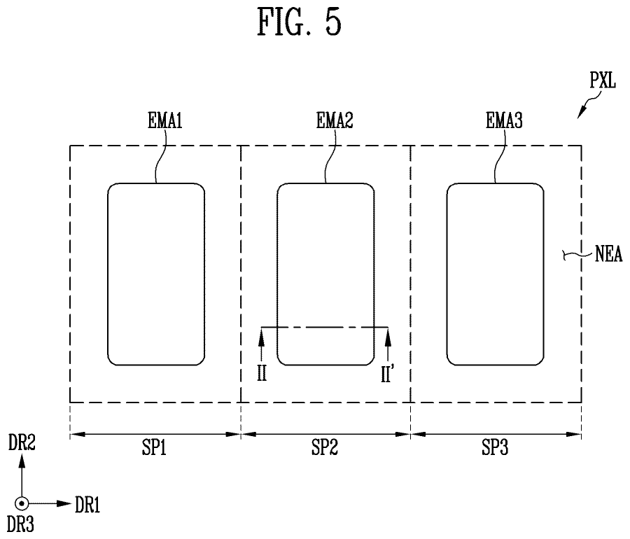

FIG. 5 is a plan view of an embodiment of one of the pixels PXL of FIG. 2.

Referring to FIGS. 2 and 5, one pixel PXL may include first to third sub-pixels SP1 to SP3 that are adjacent to each other and arranged along the first direction DR1.

The first sub-pixel SP1 may include a first emission area EMA1 and a non-emission area NEA around the first emission area EMA1. The second sub-pixel SP2 may include a second emission area EMA2 and a non-emission area NEA around the second emission area EMA2. The third sub-pixel SP3 may include a third emission area EMA3 and a non-emission area NEA around the third emission area EMA3.

The first emission area EMA1 may be an area where light is emitted from a light emitting element corresponding to the first sub-pixel SP1. The second emission area EMA2 may be an area where light is emitted from a light emitting element corresponding to the second sub-pixel SP2. The third emission area EMA3 may be an area where light is emitted from a light emitting element corresponding to the third sub-pixel SP3. As described with reference to FIG. 5, each of the emission areas EMA1 to EMA3 may correspond to an opening OP (see FIG. 6) in a pixel definition layer PDL with three of the openings OP respectively corresponding to the first to third sub-pixels SP1 to SP3.

FIG. 6 is a cross-sectional view taken along a line II-II′ of FIG. 5 and particularly shows cross-sections of portions of the display panel DP and the cover window WD associated with the second sub-pixel SP2.

Referring to FIGS. 5 and 6, the display panel DP may include the substrate SUB, a pixel circuit layer PCL, a light emitting element layer LDL, a thin film encapsulation layer TFE, and a color filter layer CFL. The cover window WD may be on the display panel DP. In FIG. 6, the second sub-pixel SP2 is shown as an example, and the first and third sub-pixels SP1 to SP3 may be configured similarly to the second sub-pixel SP2.

The substrate SUB may include a silicon wafer substrate formed using a semiconductor process. For example, the substrate SUB may include silicon, germanium, and/or silicon-germanium.

The pixel circuit layer PCL may be on the substrate SUB. The pixel circuit layer PCL may include circuit elements of the second sub-pixel SP2. For example, the pixel circuit layer PCL may include the transistor TR of the second sub-pixel SP2. The transistor TR of the second sub-pixel SP2 may be any one of the transistors included in the sub-pixel circuit of the second sub-pixel SP2.

The transistor TR of the second sub-pixel SP2 may include an active layer ACT, a source electrode SE, a drain electrode DE, and a gate electrode GE.

The active layer ACT of the transistor TR may be disposed on a buffer layer BFF. The active layer ACT may include a first region contacting the source electrode SE and a second region contacting the drain electrode DE. An area between the first area and the second area may be a channel area.

In some embodiments, the active layer ACT may be a portion of a semiconductor pattern made of polysilicon, amorphous silicon, oxide semiconductor, etc. The channel region may be an intrinsic semiconductor that is not doped with the impurity. The first region and the second region may be a semiconductor doped with impurities. Here, the impurity may be n-type impurity, p-type impurity, or other impurity such as metal.

A gate insulating layer GISL may be on the active layer ACT. The gate insulating layer GISL may include an inorganic insulating layer containing an inorganic material or an organic insulating layer containing an organic material.

The gate electrode GE of the transistor TR may be on the active layer ACT with the gate insulating layer GISL interposed between the gate electrode and the active layer ACT.

An interlayer insulating layer ILD may be on the gate electrode GE. The interlayer insulating layer ILD may include an inorganic insulating layer containing an inorganic material or an organic insulating layer containing an organic material.

The source electrode SE of the transistor TR may be connected to the active layer ACT through the first via hole VIA1 penetrating the interlayer insulating layer ILD and the gate insulating layer GISL. For example, the source electrode SE of the transistor TR may be electrically connected to the first region of the active layer ACT through the first via hole VIA1.

The drain electrode DE of the transistor TR may be connected to the active layer ACT through the second via hole VIA2 penetrating the interlayer insulating layer ILD and the gate insulating layer GISL. For example, the drain electrode DE of the transistor TR may be electrically connected to the second region of the active layer ACT through the second via hole VIA2.

In FIG. 6, the drain electrode DE of the transistor TR is shown as being connected to a first electrode AE of the light emitting element LD, but embodiments are not limited thereto. For example, the source electrode SE of the transistor TR may be connected to the first electrode AE.

The protective layer PSV may be on the transistor TR and may cover the transistor TR. The protective layer PSV may include a third via hole VIA3 exposing a portion of the drain electrode DE of the transistor TR.

The light emitting element layer LDL may be on the protective layer PSV and may include a light emitting element LD that emits light.

The light emitting element LD may include the first electrode (or anode electrode) AE, a second electrode (or cathode electrode) CE, and a light emitting layer EML disposed between the first and second electrodes AE and CE.

The first electrode AE may be electrically connected to the drain electrode DE of the transistor TR through the third via hole VIA3 penetrating the protective layer PSV. The first electrode AE may include a reflective layer (not shown) that can reflect light and a transparent conductive layer (not shown).

The light emitting element layer LDL may further include a pixel definition layer PDL having an opening OP overlying a portion of the first electrode AE. For example, the second sub-pixel SP2 may include a second emission area EMA2 and a non-emission area NEA adjacent to the second emission area EMA2. The second emission area EMA2 may correspond to a portion area of the first electrode AE overlapping the opening OP. The light emitting layer EML may include, but is not limited to, a light generating layer that emits light, an electron transport layer that transports electrons, and a hole transport layer that transports holes.

The emissive layer EML may include organic materials and/or inorganic materials. Although the patterned light emitting layer EML is shown as an example in FIG. 6, the light emitting layer EML may be a continuous layer extending across multiple sub-pixels SP. The color of light generated in the light emitting layer EML may be one of red, green, blue, and white, but is not limited thereto. For example, the color of light generated in the emission layer EML may be one of magenta, cyan, and yellow.

The second electrode CE may be on the light emitting layer EML and may cover the light emitting layer EML. The second electrode CE may be a continuous layer extending to multiple sub-pixels SP.

A thin film encapsulation layer TFE may be on the second electrode CE and may cover the second electrode CE. The thin film encapsulation layer TFE may have a single-layer or multi-layer structure. The thin film encapsulation layer TFE may include a plurality of insulating layers covering the light emitting element LD. The thin film encapsulation layer TFE may include at least one inorganic layer and at least one organic layer. For example, the thin film encapsulation layer TFE may have a structure in which inorganic and organic layers are alternately stacked.

A light blocking member BM and color filters CF1 to CF3 may be on the encapsulation layer TFE. The light blocking member BM may be in an area that does not overlap the light emitting layer EML. For example, the light blocking member BM may overlap the non-emission area NEA. The color filters CF1 to CF3 may include a first color filter CF1, a second color filter CF2, and a third color filter CF3.

An adhesive layer ADL may be on the color filters CF1 to CF3. The cover window WD may be attached to the display panel DP through the adhesive layer ADL. The adhesive layer ADL may include an optically clear adhesive film (OCA). However, the adhesive layer ADL is not limited thereto and may include conventional bonds or adhesives. For example, the adhesive layer ADL may include optically clear adhesive resin (OCR) or pressure sensitive adhesive (PSA) film.

The cover window WD may include a cover glass layer CGL and at least one coating layer CTL on the cover glass layer CGL. In the display device DD, the coating layer CTL may be on the upper surface S1 of the cover glass layer CGL, and the display panel DP may be on the lower surface S2 of the cover glass layer CGL with the adhesive layer ADL interposed therebetween. Here, the coating layer CTL may include at least one of an anti-reflection coating layer, an anti-fingerprint coating layer, and an anti-glare coating layer. For example, the coating layer CTL may include a first coating layer CTL1 and a second coating layer CTL2 sequentially stacked on the cover glass layer CGL. The first coating layer CTL1 may be an anti-reflection coating layer. The second coating layer CTL2 may be an anti-fingerprint coating layer. However, embodiments of the present disclosure are not limited thereto. For example, the coating layer CTL may include an anti-glare coating layer.

As shown in FIG. 6, the display device DD may not include a polarization layer. When the polarization layer is not included, the light output efficiency of the display panel DP may increase, and color reproducibility may also increase. On the other hand, external light reflectance may increase, and the cover window WD may include a coating layer CTL such as an anti-reflection coating layer to reduce the reflectance. Combining the cover window WD including the coating layer CTL with the display panel DP could cause the display panel DP to display a blue color rather than a black color when the display panel DP is in an off state. In the display device DD according to this embodiment, the coating layer CTL has a color difference value adjusted depending on a color difference value of the display panel DP, so that a black color is visible on the display panel DP in the off state.

According to some embodiments, when the display panel DP has a first color difference value in the color coordinate system, the coating layer CTL disposed on the display panel DP may have a second color difference value different from the first color difference value. A color difference may be defined as a separation between two colors in color space, and the first color difference value may be the color difference between a measured color of the display panel DP and an origin of the coordinate system for color space. The second color difference value of the coating layer CTL may be set so that the sum of the first color difference value and the second color difference value may be adjacent to the origin of the color coordinate system.

The first and second color difference values may be values obtained by measuring light that reaches the display panel DP and the coating layer CTL and is reflected therefrom, respectively. The first and second color difference values may be based on specular component included (SCI) reflectance or specular component excluded (SCE) reflectance. The SCI reflectance may be integrated reflectance and may be a result of measuring collimated light and diffuse light that reach (incident on) the surface and are reflected therefrom. The SCE reflectance may be scattered reflectance and may be a result of measuring diffuse light that reaches (incidents on) the surface and is reflected therefrom. Specifically, the SCI reflectance or SCE reflectance may be a result of measuring incident light and reflected light with a reflectance measurement apparatus such as CM-2600D, CM-700D, CM-3700A, or LAMBDA-950. For example, the SCI reflectance or SCE reflectance may indicate a reflected color measured from the front of the display device DD in an off state when the screen is not turned on. The reflected color may be expressed using CIE Lab's color coordinates: first color coordinate (a*) and second color coordinate (b*). The first color coordinate may indicate a degree of red (positive (+) value) or green (negative (−) value), and the second color coordinate may indicate a degree of yellow (positive (+) value) or blue (negative (−) value).

In the case of a display device DD that does not include a polarization layer, the SCI reflectance (a*, b*) may be (−0.7, −9.0), or the SCE reflectance (a*, b*) may be (+3.0, −0.5). The reflectance may be a color difference value indicating that the display device DD appears to have a blue color when the display device DD is in an off state. This may mean that distortion may occur in the color of light the display device DD provides to the user when on. Accordingly, the coating layer CTL may be set to have a color difference value to compensate for the color of the display panel DP.

In one embodiment in accordance with the present disclosure, when the display panel DP has the first color difference value, the coating layer CTL may be set to have a second color difference value to compensate for the first color difference value of the display panel DP. By forming the coating layer CTL having the second color difference value on the display panel DP, the SCI reflectance (a*, b*) or SCE reflectance (a*, b*) of the display device DD may be changed. In the display device DD including the coating layer CTL having the second color difference value, the SCI reflectance (a*, b*) may be (0, 0) or the SCE reflectance (a*, b*) of the display device DD may be (0, 0). This may mean that the display device DD appears to have the black color rather than the blue color when the display device DD is in an off state. That is, the display device DD may have color coordinates adjacent to the origin regardless of the color variation of the display panel DP through the coating layer CTL whose color difference value is adjusted. This may mean that there is no distortion in the color of light provided to the user, so color purity may be excellent.

FIG. 7 shows plots in color space coordinates for color difference values according to embodiments of the present disclosure.

FIG. 7 particularly shows color difference values of SCI reflectance, the horizontal axis may be the first color coordinate (a*), which is a color coordinate in the color coordinate system defined by CIE Lab, and the vertical axis may be the second color coordinate (b*), which is another color coordinate in the color coordinate system defined by CIE Lab. The first color coordinate, when a positive (+) value, may represent a red color, and the first color coordinate, when a negative (−) value, may represent a green color. The second color coordinate, when a positive (+) value, may represent a yellow color, and the second color coordinate, when a negative (−) value, may represent a blue color. The a* and b* axes of the color coordinate system may be unbounded and may exceed about +150 to cover the human gamut.

As the first and second color coordinates are adjacent to the origin, the black color may be recognized. For example, when the SCI reflectance of the display device DD has the first color coordinate in a range from −1 to 1 and the second color coordinate in a range from −1 to 1, the black color may be visible in the off state of the display device DD.

According to some embodiments, in the display device DD, the color difference value of the coating layer CTL is set depending on the color difference value of the display panel DP, so that a black color may be visible when the display panel DP is in an off state. For example, when the display panel DP has the first color difference value and the coating layer CTL has the second color difference value, the second color difference value (a*_2, b*_2) of the coating layer CTL may be calculated using Equation 1.

$${a}^{*} \_ 2 \geq {k}_{a} \times ( {a}^{*} \_ 1 ) + α , \qquad ( Equation 1 )$$

$${b}^{*} \_ 2 \geq {k}_{b} \times ( {b}^{*} \_ 1 ) + β ,$$

$$0.5 \leq {k}_{a} , {k}_{b} \leq 1 , - 0.6 \leq α \leq 0 , - 3 \leq β \leq 1.5$$

In Equation 1, a*_1 is the first color coordinate of the first color difference value, a*_2 is the first color coordinate of the second color difference value, b*_1 is the second color coordinate of the first color difference value, and b*_2 is the second color coordinate of the second color difference value. Additionally, the display panel DP having the first color difference value refers to the display panel DP before being combined with the coating layer CTL.

Referring to FIG. 7, the display panel DP may have a first color difference value within the color difference value range RG_PN. More specifically, the first color coordinate of the first color difference value of the display panel DP may be in a range from −3.0 to 3.0, and the second color coordinate of the first color difference value of the display panel DP may be in a range from −3.0 to 3.0. The color difference value range RG_PN of the display panel DP may include color difference values for which blue color is visible when the display device DD is in an off state.

The color difference value range RG_CTL of the coating layer CTL may be set depending on the color difference value range RG_PN of the display panel DP. The color difference value range RG_CTL of the coating layer CTL may be set so that the display device DD has the target color difference value range RG_T. The second color difference value of the coating layer CTL may have a first color coordinate within a range from −3.6 to 3.0, and a second color coordinate within a range from −6.0 to 4.5. However, the range may change depending on the color difference value range RG_PN of the display panel DP, and the range for the second color difference value is not limited to the specific example shown in FIG. 7.

For example, the second color difference value may be set so that the sum with the first color difference value may be adjacent to the origin the color coordinate system. The second color difference value may be set so that each coordinate of the sum of the first color difference value and the second color difference value is in a range from −1 to 1. For example, when the first color coordinate of the first color difference value of the display panel DP is −0.52, the first color coordinate of the first color difference value of the coating layer CTL may be 0.52. However, this is an example, and other embodiments are not limited thereto as long as Equation 1 is satisfied.

The target color difference value range RG_T may refer to the color difference value range of the display device DD when the coating layer CTL is combined on the display panel DP. The target color difference value of the display device DD may belong to the target color difference value range RG_T, where both color coordinates are in the range from −1 to 1. The first color coordinate of the target color difference value may be in a range from −1.0 to 1.0, and the second color coordinate of the target color difference value may be in a range from −1.0 to 1.0. The target color difference value range RG_T may include color difference values adjacent to the origin of the color coordinate system. The color difference value of the display device DD may be the sum of the first color difference value of the display panel DP and the second color difference value of the coating layer CTL. The sum of the first color difference value and the second color difference value may be adjacent to the origin of the color coordinate system. When the coating layer CTL includes a plurality of layers, the color difference value of the display device DD may be determined by adding the first color difference value and the sum of the second color difference values of the plurality of layers om the coating layer CTL.

In the example of FIG. 6, when the first and second coating layers CTL1 and CTL2 are on the cover glass CGL (see FIG. 6), the sum of the first color difference value of the display panel DP, the color difference value of the first coating layer CTL1, and the color difference value of the second coating layer CTL2 may be within the target color difference value range RG_T. The coordinates of the sum of the first color difference value of the display panel DP, the color difference value of the first coating layer CTL1, and the color difference value of the second coating layer CTL2 may all be in a range from −1 to 1. Color difference values in the target color difference value range RG_T may provide the display device with a black color when the display device DD is in an off state.

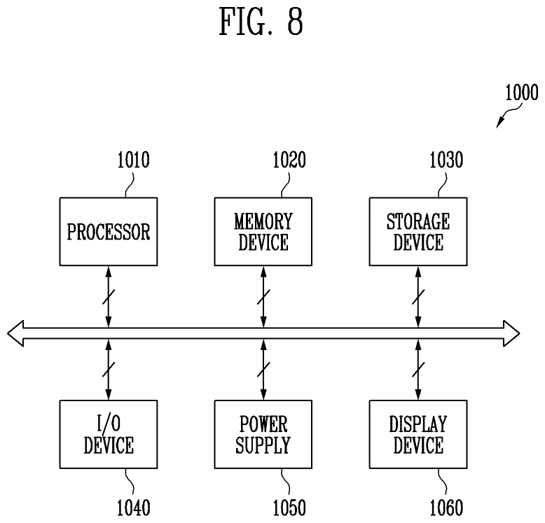

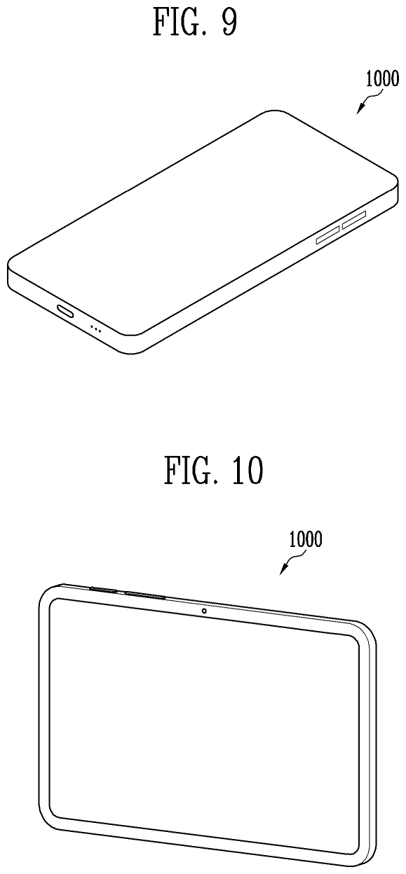

FIG. 8 is a schematic block diagram illustrating an electronic device 1000 including a display device in accordance with an embodiment. FIG. 9 is a schematic diagram illustrating an example where the electronic device 1000 of FIG. 8 is a smartphone. FIG. 10 is a schematic diagram illustrating an example where the electronic device 1000 of FIG. 8 is a tablet computer.

Referring to FIGS. 8 to 10, the electronic device 1000 may include a processor 1010, a memory device 1020, a storage device 1030, an input/output (I/O) device 1040, a power supply 1050, and a display device 1060. The display device 1060 may be the display device DD of FIG. 1. The electronic device 1000 may further include various ports for communication with a video card, a sound card, a memory card, a USB device, or other systems. In an embodiment, as illustrated in FIG. 9, the electronic device 1000 may be a smartphone. In an embodiment, as illustrated in FIG. 10, the electronic device 1000 may be a tablet computer. However, the aforementioned examples are illustrative, and the electronic device 1000 is not necessarily limited to the aforementioned examples. For example, the electronic device 1000 may be a cellular phone, a video phone, a smart pad, a smartwatch, a navigation device for vehicles, a computer monitor, a laptop computer, a head-mounted display device, or the like.

The processor 1010 may perform specific calculations or tasks. In an embodiment, the processor 1010 may be a microprocessor, a central processing unit, an application processor, or the like. The processor 1010 may be connected to other components through an address bus, a control bus, a data bus, and the like. In an embodiment, the processor 1010 may be connected to an expansion bus such as a peripheral component interconnect (PCI) bus. In an embodiment, the processor 1010 may provide input image data to the display device 1060. Hence, the display device 1060 may display an image based on the input image data provided from the processor 1010.

The memory device 1020 may store data needed to perform the operation of the electronic device 1000. The memory device 1020 may function as a working memory and/or a buffer memory for the processor 1010. For example, the memory device 1020 may include one or more volatile memory devices such as a dynamic random access memory (DRAM) device, a static random access memory (SRAM) device, and a mobile DRAM device.

The storage device 1030 may store data in response to control signals or data from the processor 1010. The storage device 1030 may include one or more non-volatile storages to retain the data even when the electronic device 1000 is powered off. In some embodiments, the storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be integrated with the I/O device 1040.

The power supply 1050 may supply power needed to perform the operation of the electronic device 1000. For example, the power supply 1050 may include a power management integrated circuit (PMIC). In an embodiment, the power supply 1050 may supply power to the display device 1060.

The display device 1060 may display images in response to control signals or data from the processor 1010. The display device 1060 may be connected to other components through the buses or other communication links

According to embodiments of the present disclosure, the display device may include the coating layer CTL having a color difference value that compensates for the color difference value of the display panel DP, so the display device DD may have color coordinates adjacent to the origin of the color coordinate system even if the color value of the display panel DP is far from the origin in the color coordinate system. To this end, the coating layer CTL may have a color difference value such that black color is visible when the display device DD is in an off state. As such, the display devices according to embodiments of the present disclosure can improve display quality by including a coating layer having a color difference value to compensate for the color difference value of the display panel.

According to embodiments of the present disclosure, a display device with improved display quality and a manufacturing method thereof are provided.

Effects according to embodiments are not limited by contents exemplified above, and other effects are included in the present specification.

Although specific embodiments and applications are described herein, other embodiments and variations may be derived from the above description. Accordingly, the spirit of the present disclosure is not limited to these embodiments but extends to the scope of the claims set forth below, various obvious modifications, and equivalents.

What is claimed is:

1. A display device comprising:
a display panel capable of displaying an image; and
a cover window disposed on the display panel, wherein
the cover window includes
a cover glass layer; and
at least one coating layer disposed on the cover glass layer, and
the display panel has a first color difference value in a color coordinate system,
the at least one coating layer has a second color difference value in the color coordinate system, and
a sum of the first color difference value and the second color difference value is adjacent to an origin of the color coordinate system.

2. The display device of claim 1, wherein
the first color difference value is a measurement value of light that reaches the display panel and is reflected therefrom, and
the second color difference value is a measurement value of light that reaches the at least one coating layer and is reflected therefrom.

3. The display device of claim 1, wherein
the first and second color difference values are SCI (specular component included) reflectances or SCE (specular component excluded) reflectances.

4. The display device of claim 1, wherein
each color coordinate of the sum of the first color difference value and the second color difference value is in a range from −1 to 1.

5. The display device of claim 1, wherein
each of the first and second color difference values includes
a first color coordinate and a second color coordinate, and
a sum of the first color coordinate of the first color difference value and the first color coordinate of the second color difference value is in a range from −1 to 1, and a sum of the second color coordinate of the first color difference value and the second color coordinate of the second color difference value is in a range from −1 to 1.

6. The display device of claim 5, wherein
the first color coordinate of the first color difference value is in a range from −3 to 3, and
the second color coordinate of the first color difference value is in a range from −3 to 3.

7. The display device of claim 5, wherein
the second color difference value is determined based on Equation 1 below,
$${a}^{*} \_ 2 \geq {k}_{a} \times ( {a}^{*} \_ 1 ) + α , \qquad ( Equation 1 )$$
$${b}^{*} \_ 2 \geq {k}_{b} \times ( {b}^{*} \_ 1 ) + β ,$$
$$0.5 \leq {k}_{a} , {k}_{b} \leq 1 , - 0.6 \leq α \leq 0 , - 3 \leq β \leq 1.5$$
here, a*_1 is the first color coordinate of the first color difference value, a*_2 is the first color coordinate of the second color difference value, b*_1 is the second color coordinate of the first color difference value, and b*_2 is the second color coordinate of the second color difference value.

8. The display device of claim 5, wherein
when the first and second color coordinates are positive values, the first and second color coordinates correspond to red and yellow colors, respectively, and
when the first and second color coordinates are negative values, the first and second color coordinates correspond to green and blue colors, respectively.

9. The display device of claim 1, wherein
the second color difference value is set to give the display device a black color when the display panel is in an off state.

10. The display device of claim 1, wherein
the display device does not include a polarization layer.

11. The display device of claim 1, wherein
the at least one coating layer includes an anti-reflection coating layer, an anti-fingerprint coating layer, or an anti-glare coating layer.

12. The display device of claim 1, wherein
the at least one coating layer includes a first coating layer on the cover glass, and a second coating layer on the first coating layer,
the first coating layer has a third color difference value in the color coordinate system,
the second coating layer has a fourth color difference value in the color coordinate system, and
a sum of the first color difference value, the third color difference value, and the fourth color difference value is adjacent to the origin of the color coordinate system.

13. The display device of claim 12, wherein
a sum of the first color difference value, the third color difference value, and the fourth color difference value is in a range from −1 to 1.

14. The display device of claim 1, further comprising
a bonding layer between the display panel and the cover glass layer.

15. The display device of claim 1, wherein
the display panel includes
a substrate;
a circuit element layer on the substrate and including a plurality of transistors; and
a light emitting element layer on the circuit element layer and including light emitting elements respectively connected to the plurality of transistors.

16. An electronic device, comprising:
a processor to provide input image data; and
a display device to display an image based on the input image data,
wherein the display device comprises:
a display panel capable of displaying an image; and
a cover window disposed on the display panel, wherein
the cover window includes
a cover glass layer; and
at least one coating layer disposed on the cover glass layer, and
the display panel has a first color difference value in a color coordinate system,
the at least one coating layer has a second color difference value in the color coordinate system, and
a sum of the first color difference value and the second color difference value is adjacent to an origin of the color coordinate system.

17. The electronic device of claim 16, wherein
the first color difference value is a measurement value of light that reaches the display panel and is reflected therefrom, and
the second color difference value is a measurement value of light that reaches the at least one coating layer and is reflected therefrom.

18. The electronic device of claim 16, wherein
each color coordinate of the sum of the first color difference value and the second color difference value is in a range from −1 to 1.

19. The electronic device of claim 16, wherein
the at least one coating layer includes a first coating layer on the cover glass, and a second coating layer on the first coating layer,
the first coating layer has a third color difference value in the color coordinate system,
the second coating layer has a fourth color difference value in the color coordinate system, and
a sum of the first color difference value, the third color difference value, and the fourth color difference value is adjacent to the origin of the color coordinate system.

20. The electronic device of claim 19, wherein
a sum of the first color difference value, the third color difference value, and the fourth color difference value is in a range from −1 to 1.
